(19) United States
(12) Patent Application Publication
(10) Pub. No.: US 2020/0025827 A1
(43) Pub. Date: Jan. 23, 2020

(54) REMAINING BATTERY POWER MEASURING DEVICE, METHOD OF MEASURING REMAINING BATTERY POWER, AND STORAGE MEDIUM

(71) Applicant: FUJITSU LIMITED, Kawasaki-shi (JP)

(72) Inventors: Kenichi Kawasaki, Kawasaki (JP); Hiroyuki Nakamoto, Kawasaki (JP); Toshihiro Yamanaka, Itoshima (JP); Yoshiyuki Jufuku, Itoshima (JP)

(73) Assignee: FUJITSU LIMITED, Kawasaki-shi (JP)

(21) Appl. No.: 16/508,982

(22) Filed: Jul. 11, 2019

(30) Foreign Application Priority Data
Jul. 23, 2018 (JP) 2018-137643

(51) Int. Cl. G01R 31/367; G01D 5/00; G01R 31/3835

(52) U.S. Cl. CPC G01R 31/367; G01R 31/3835; G01D 5/00

(57) ABSTRACT

A remaining battery power measuring device includes a memory and a processor coupled to the memory and configured to detect an operation time period of an object that is to be measured and intermittently operates by power supplied from a battery, adjust time when a battery voltage of the battery is measured, based on the operation time period detected by the processor and measure the battery voltage at the time adjusted by the processor.

### CROSS-REFERENCE TO RELATED APPLICATION

This application is based upon and claims the benefit of priority of the prior Japanese Patent Application No. 2018-137643, filed on Jul. 23, 2018, the entire contents of which are incorporated herein by reference.

### FIELD

The embodiments relate to a remaining battery power measuring device, a method of measuring remaining battery power, and a remaining battery power measurement program.

### BACKGROUND

It is desirable that a device to be driven by a battery accurately measure, in real time, information indicating remaining battery power after a battery is replaced or charged, or indicating whether remaining battery power becomes zero, or the like. Since an open circuit voltage (OCV) of a battery accurately indicates a remaining battery power characteristic, remaining battery power may be estimated by measuring a battery voltage. However, since the battery voltage varies depending on an operation of an object to be measured, it is difficult to properly estimate the remaining battery power. Thus, a technique for estimating remaining power by determining an operational mode of an object to be measured, determining an operational mode in which measurement is executed, and measuring a battery voltage has been disclosed. However, since the battery voltage varies depending on a mode in which the measurement is executed, a technique for calculating an average voltage to reduce the variation and improving the accuracy of estimating remaining battery power has been disclosed.

As related art, Japanese Laid-open Patent Publication No. 6-224844 and Japanese Laid-open Patent Publication No. 10-229646 have been disclosed.

However, to calculate the average voltage to reduce the variation in the battery voltage, the battery voltage is continuously measured for a long time period. Thus, a current to be consumed for the measurement is large.

Under such circumstances, it is desirable to provide a remaining battery power measuring device, a method of measuring remaining battery power, and a remaining battery power measurement program that may improve the accuracy of estimating remaining battery power with low power.

### SUMMARY

According to an aspect of the embodiments, a remaining battery power measuring device includes a memory and a processor coupled to the memory and configured to detect an operation time period of an object that is to be measured and intermittently operates by power supplied from a battery, adjust time when a battery voltage of the battery is measured, based on the operation time period detected by the processor and measure the battery voltage at the time adjusted by the processor.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram exemplifying an entire configuration of a sensor node according to a first embodiment;

FIG. 2 is a diagram exemplifying an open circuit voltage curve indicating relationships between an open circuit voltage of a battery and a depth of discharge of the battery and exemplifying relationships between elapsed time and a battery voltage;

FIG. 3A is a diagram exemplifying relationships between elapsed time and a current flowing to a sensor and FIG. 3B is a diagram exemplifying an operation detection signal;

FIG. 4A is a diagram exemplifying a structure of an operation detector in detail and FIGS. 4B to 4D are diagrams exemplifying signals;

FIGS. 5A and 5B are diagrams exemplifying relationships between an operation time period of the sensor and a restoration time period;

FIGS. 6A and 6B are diagrams exemplifying the generation of a time adjustment table;

FIG. 7A is a diagram illustrating an example of an operation of the sensor, FIG. 7B is a diagram exemplifying an operation detection signal, and FIG. 7C is a diagram exemplifying the time adjustment table;

FIG. 8 is a diagram exemplifying a time chart indicating a time adjustment algorithm;

FIG. 9 is a diagram exemplifying a voltage measurer and a remaining power estimator in detail;

FIG. 10 is a diagram exemplifying a flowchart indicating operations of the sensor node;

FIG. 11 is a diagram exemplifying a time chart in the case where a process to be executed in accordance with the flowchart illustrated in FIG. 10 is applied to the time chart illustrated in FIG. 8;

FIGS. 12A and 12B are diagrams exemplifying cases where remaining battery power is estimated when a request signal is input;

FIG. 13 is a diagram exemplifying a flowchart of a time adjuster in the case where a request signal is received and remaining battery power is estimated;

FIG. 14 is a diagram exemplifying a time chart in the case where a request signal is received and remaining battery power is estimated;

FIG. 15A is a diagram exemplifying the case where alarm transmission is executed when a timer periodically requests the estimation of remaining battery power and FIG. 15B is a diagram exemplifying the case where alarm transmission is executed when a controller requests the estimation of remaining battery power;

FIG. 16 is a diagram exemplifying a flowchart of the time adjuster in the case where alarm transmission is executed;

FIG. 17A is a diagram exemplifying the case where a sensing operation is suspended when the timer periodically requests the estimation of remaining battery power and FIG. 17B is a diagram exemplifying the case where the sensing operation is suspended when the controller requests the estimation of remaining battery power;

FIG. 18 is a diagram exemplifying a flowchart of the time adjuster in the case where the sensing operation is suspended;

FIG. 19 is a diagram exemplifying a time chart in the case where the flowchart illustrated in FIG. 18 is applied when the frequency at which the sensing operation is executed is high; and

FIG. 20 is a diagram exemplifying a hardware configuration of the time adjuster.

### DESCRIPTION OF EMBODIMENTS

Before a description of embodiments, an overview of the estimation of remaining battery power is described below. For example, it is considered that most of many sensor nodes installed to acquire environmental data are battery driving devices, since it is difficult to ensure power supplies via cables. For example, since sewage overflow systems are installed immediately under maintenance holes in order to sense water levels of sewers, it is difficult to connect power supply lines to sensor nodes. Thus, the sensor nodes are of a battery-driven type.

Since the cost of replacing batteries in the sensor nodes of the battery-driven type is high, it is preferable to extend the life of the batteries as much as possible. Thus, intermittent operation control is executed to stop a sensing operation to suppress power to be wastefully consumed in a time zone in which data is not acquired and execute the sensing operation only when data is acquired.

In addition, it is important to continue an operation in an environmental sensing system. Thus, when remaining battery power of a sensor node becomes zero and a state in which data is not able to be acquired continues, the reliability of the system may be significantly reduced. It is, therefore, preferable that time when a battery is replaced be accurately measured for a primary battery-driven sensor node and that time when a battery such as a lithium ion battery is charged be accurately measured for a secondary battery-driven sensor node. Thus, a technique for measuring remaining battery power with high accuracy is important.

For example, it is considered that a battery open circuit voltage (OCV) management table indicating a remaining battery power characteristic with high accuracy is held and current remaining battery power is estimated by measuring a current battery voltage. However, since the battery voltage largely varies depending on an operational state of a sensor node, a remaining battery power error may be large depending on measurement time.

Thus, it is considered that a battery voltage when an operational mode of an object to be measured is monitored and changed to a standby mode is measured. Since the battery voltage varies even in the standby mode, remaining battery power is estimated with high accuracy by continuously measuring the battery voltage to calculate an average voltage and reducing the variation in the battery voltage. However, to calculate the average voltage to reduce the variation in the battery voltage, the battery voltage is continuously measured for a long time period. Thus, a current to be consumed for the measurement is large.

The following embodiments describe a remaining battery power measuring device, a method of measuring remaining battery power, and a remaining battery power measurement program that may improve the accuracy of estimating remaining battery power with low power.

### First Embodiment

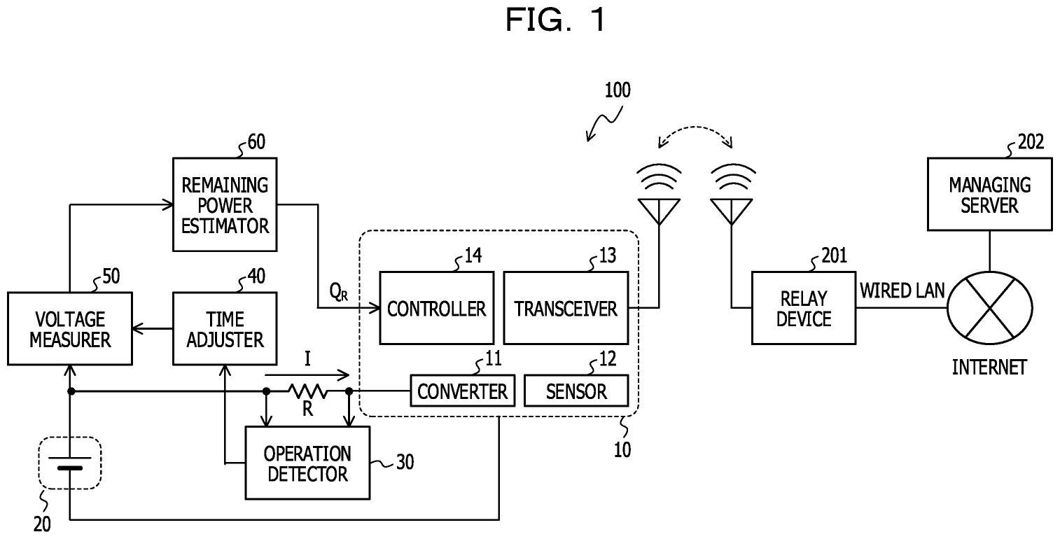

FIG. 1 is a block diagram exemplifying an entire configuration of a sensor node 100 according to a first embodiment. As exemplified in FIG. 1, the sensor node 100 includes a sensor unit 10, a battery 20, an operation detector 30, a time adjuster 40, a voltage measurer 50, and a remaining power estimator 60. The sensor unit 10 includes a converter 11, a sensor 12, a transceiver 13, and a controller 14.

The converter 11 converts power of the battery 20 to power for the sensor 12. The sensor 12 uses the power obtained by the conversion by the converter 11 to acquire data. The sensor 12 is, for example, a water level gauge, a thermometer, a hygrometer, an accelerometer, or the like. The transceiver 13 transmits the data acquired by the sensor 12. The controller 14 controls operations of the converter 11, the sensor 12, the transceiver 13, and the like.

The data transmitted by the transceiver 13 is received by a relay device 201 that includes a transceiver. The relay device 201 transmits the data to a managing server 202 via a telecommunications line such as the Internet. The managing server 202 uses the received data to execute analysis.

The controller 14 stops a sensing operation of the sensor 12 in a time zone in which data is not to be acquired. The controller 13 causes the sensor 12 to execute the sensing operation when data is to be acquired. For example, the controller 14 causes the sensor 12 to execute the intermittent operation. For example, after an initial connection operation of the sensor 12 is completed, the controller 14 causes the sensor 12 to execute the sensing operation at fixed time intervals. By executing this, power to be consumed may be suppressed and the life of the battery 20 may be extended. In a state in which the operation of the sensor 12 is stopped, a current flowing from the battery 20 to the sensor 12 is equal to or smaller than a predetermined threshold. The state in which the operation of the sensor 12 is stopped includes a state in which a current corresponding to standby power flows to the sensor 12. The predetermined threshold is determined as a sufficiently small current value that causes the voltage of the battery 20 to be restored to the open circuit voltage (OCV). For example, when a current that exceeds the threshold continuously flows, the voltage of the battery 20 is not restored to the open circuit voltage.

The operation detector 30 detects an operation of the sensor unit 10. The time adjuster 40 adjusts time when a battery voltage V_{BAT} of the sensor unit 10 is measured, based on a temporal variation in the battery voltage V_{BAT}. The voltage measurer 50 measures the battery voltage V_{BAT} of the battery 20 in accordance with the time adjusted by the time adjuster 40. The remaining power estimator 60 estimates remaining power Q_{R} of the battery 20 based on the battery voltage V_{BAT} measured by the voltage measurer 50.

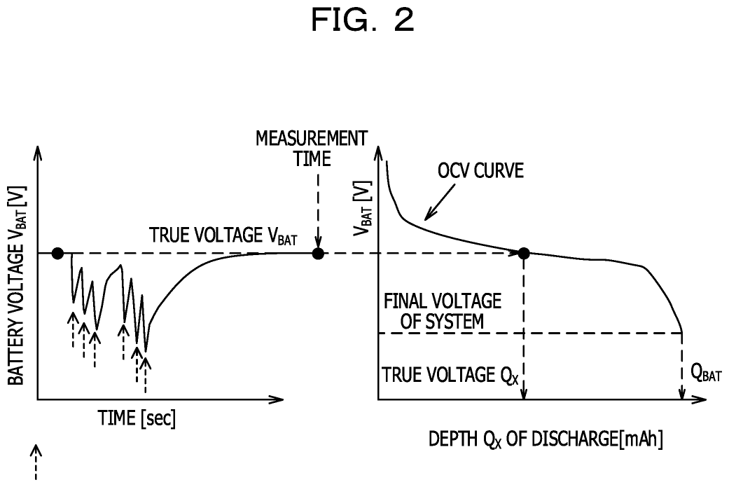

Relationships between remaining power (hereinafter referred to as remaining power Q_{R}) of the battery 20 and the voltage (open circuit voltage) of the battery 20 when the operation of the sensor unit 10 is stopped are described below. A right diagram included in FIG. 2 exemplifies an open circuit voltage curve indicating relationships between the open circuit voltage of the battery 20 and a depth Q_{X} of discharge of the battery 20. The depth Q_{X} of discharge is a parameter corresponding to remaining power of the battery 20. As the depth of discharge is larger, the remaining power of the battery 20 is lower. When the depth of discharge upon a final voltage of the battery 20 is Q_{BAT}, the remaining power Q_{R} may be represented by Q_{BAT}−Q_{X}. As exemplified in the right diagram included in FIG. 2, as the depth of discharge is larger (or as the remaining power of the battery 20 is lower), the open circuit voltage is lower. The depth of discharge and the open circuit voltage have one-to-one relationships. Thus, the remaining power Q_{R} of the battery 20 may be measured by measuring the open circuit voltage. A primary battery that is not rechargeable and a secondary battery that is rechargeable may be applied to the battery 20 according to the first embodiment as long as the depth of discharge is acquired from the open circuit voltage.

During an operation time period during which the sensor unit 10 operates and a standby time period during which the sensor unit 10 does not operate, the voltage (hereinafter referred to as battery voltage V_{BAT}) of the battery 20 is lower than the open circuit voltage. A left diagram included in FIG. 2 exemplifies relationships between elapsed time and the battery voltage V_{BAT} of the battery 20. As exemplified in the left diagram included in FIG. 2, during the operation time period of the sensor unit 10, the battery voltage V_{BAT} of the battery 20 is lower than the open circuit voltage. In the standby time period after the operation time period of the sensor unit 10, the battery voltage V_{BAT} is not quickly restored to the open circuit voltage and is restored to the open circuit voltage after a predetermined time period (restoration time period) elapses. In the first embodiment, after the restoration time period elapses after the end of the operation time period of the sensor unit 10, the battery voltage V_{BAT} of the battery 20 is measured.

In the first embodiment, the battery voltage V_{BAT} of the battery 20 changes with the intermittent operation of the sensor unit 10. Relationships with the restoration time period from the time when the sensor unit 10 stops operating to the time when the battery voltage V_{BAT} is restored to the open circuit voltage are acquired in advance, and restoration time when the battery voltage V_{BAT} is restored to the open circuit voltage may be estimated without the execution of continuous battery voltage measurement. When the battery voltage V_{BAT} is measured a predetermined number of times (for example, one time) at the restoration time, the open circuit voltage may be accurately measured while suppressing a current to be consumed for the measurement to a small value. For example, remaining power of the battery 20 may be accurately estimated with low power.

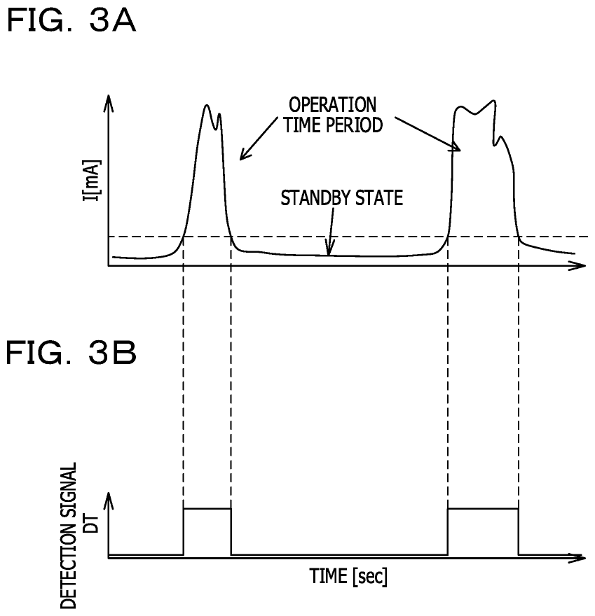

Details of operations of the sections are described below. The operation detector 30 detects a current flowing from the battery 20 to the sensor 12, thereby detecting an operation time period during which the sensor 12 operates. FIG. 3A is a diagram exemplifying relationships between elapsed time (indicated by an abscissa) and a current (indicated by an ordinate) flowing to the sensor 12. As exemplified in FIG. 3A, during each of operation time periods during which the sensor 12 operates, a current flowing to the battery 20 to the sensor 12 is large. The operation detector 30 detects the difference between potentials of both ends of a measurement resistor on a power supply line extending from the battery 20 to the sensor 12, thereby determining whether the current flowing from the battery 20 to the sensor 12 is equal to or larger than a threshold. By executing this, the operation detector 30 detects whether the sensor 12 is operating. As exemplified in FIG. 3B, when the current flowing from the battery 20 to the sensor 12 is equal to or larger than the threshold, the operation detector 30 outputs an operation detection signal DT=1 (high). When the current flowing from the battery 20 to the sensor 12 is smaller than the threshold, the operation detector 30 outputs an operation detection signal DT=0 (low).

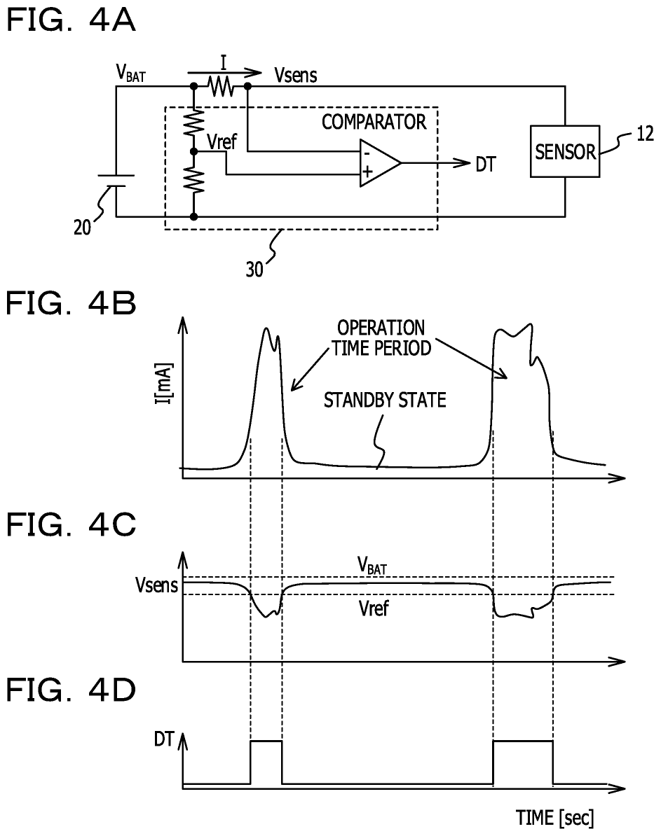

FIG. 4A is a diagram exemplifying a structure of the operation detector 30 in detail. As exemplified in FIG. 4A, the operation detector 30 executes resistance division to generate a voltage lower than the battery voltage V_{BAT} and treats the generated voltage as a reference voltage V_{ref}. The operation detector 30 uses a comparator to detect whether a measured voltage Vₛₑₙₛ that varies depending on the magnitude of the current flowing to the sensor 12 is lower than the reference voltage V_{ref}. When the measured voltage Vₛₑₙₛ is lower than the reference voltage V_{ref}, the operation detector 30 determines that the sensor 12 is operating, and the operation detector 30 outputs the operation detection signal DT=1. When the measured voltage Vₛₑₙₛ is higher than the reference voltage V_{ref}, the operation detector 30 determines that the operation of the sensor 12 has been terminated, and the operation detector 30 outputs the operation detection signal DT=0. Although power is consumed to generate the reference voltage V_{ref} by the resistance division, a current consumed for the generation is approximately 1 μA.

As exemplified in FIGS. 4B to 4D, during operation time periods during which the sensor 12 operates, the measured voltage Vₛₑₙₛ is lower than the reference voltage V_{ref}, and the operation detector 30 outputs the operation detection signal DT=1. During a time period during which the sensor 12 stands by, the measured voltage Vₛₑₙₛ is higher than the reference voltage V_{ref}, and the operation detector 30 outputs the operation detection signal DT=0.

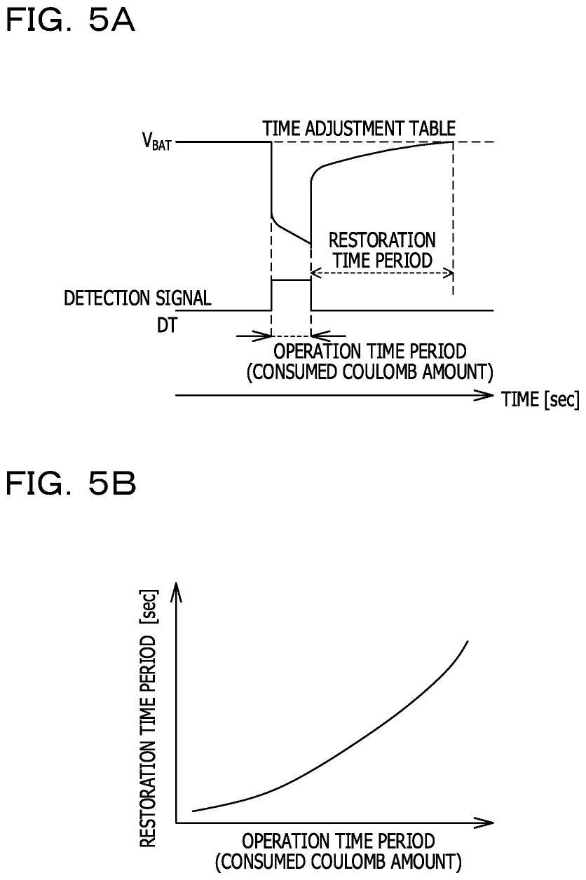

Relationships exemplified in FIG. 5A exist between the length of an operation time period during which the sensor 12 operates and a restoration time period to the time when the battery voltage V_{BAT} reduced due to the operation of the sensor 12 is restored to the open circuit voltage. The time adjuster 40 stores therein the relationships as a “time adjustment table”. As exemplified in FIG. 5B, as the length of the operation time period is longer (or a consumed Coulomb amount is larger), the time period to the time when the battery voltage V_{BAT} is restored to the open circuit voltage is longer.

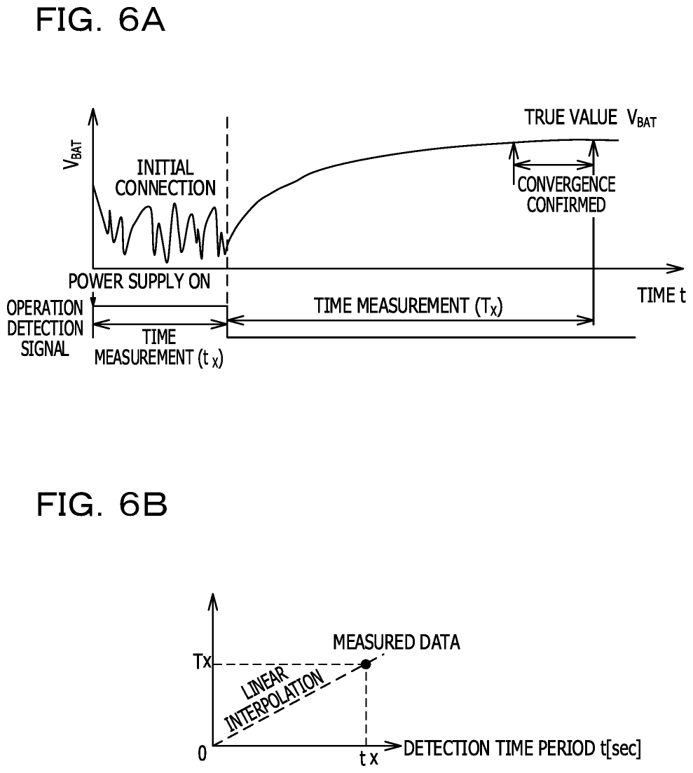

FIGS. 6A and 6B are diagrams exemplifying the generation of the time adjustment table. As exemplified in FIG. 6A, the voltage measurer 50 is set to a continuous measurement mode only immediately after a power supply is turned on. When the battery voltage V_{BAT} that is restored toward the open circuit voltage after the end of an initial operation time period t_{X} is monitored by the continuous battery voltage measurement and converges, data of a restoration time period T_{X} is acquired. For example, when a deviation from a previously measured value (for example, a value measured 5 minutes before) converges to a predetermined range (of, for example, 1% or less), the data of the restoration time period T_{X} is acquired. As exemplified in FIG. 6B, (t_{X}, T_{X}) are plotted and linear interpolation is executed on remaining data so that a line obtained by the linear interpolation extends on (0, 0), whereby the time adjustment table is generated. After the completion of the generation of the time adjustment table, the mode is changed to a normal mode to save power to be consumed.

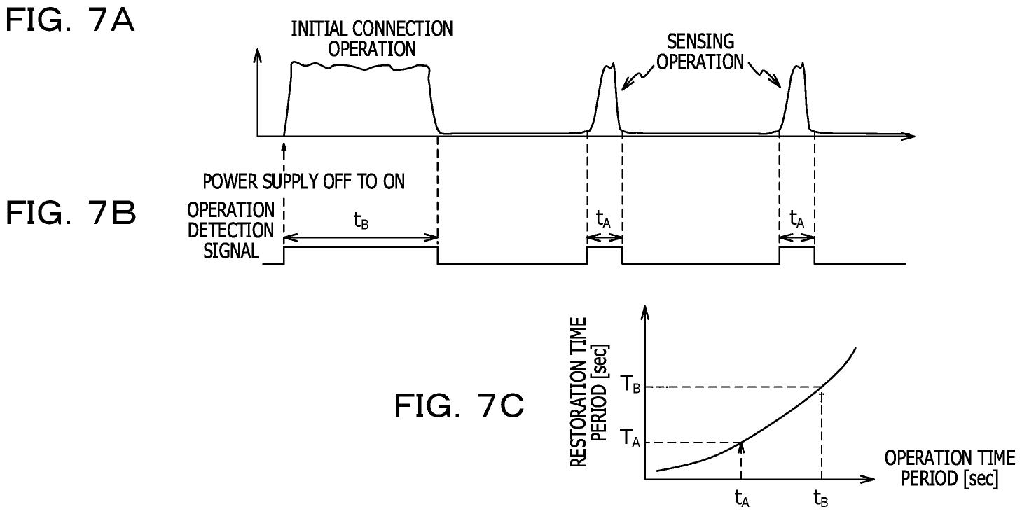

In an operational example, illustrated in FIG. 7A, of the sensor 12, after the power supply is turned on, an initial connection operation is executed to establish communication with the relay device 201. After that, the sensing operation is normally executed at predetermined time intervals. During the operations, the operation detector 30 detects an operation time period t_{B} for the initial connection and an operation time period t_{A} for the sensing operation executed by the sensor 12 once, as exemplified in FIG. 7B. The time adjuster 40 references the time adjustment table exemplified in FIG. 7C and acquires a restoration time period T_{A} corresponding to the operation time period t_{A} and a restoration time period T_{B} corresponding to the operation time period t_{B}. After the operation detection signal DT is changed from 1 to 0 and a restoration time period elapses, the time adjuster 40 outputs a measurement instruction signal EN=1 and permits the voltage measurement.

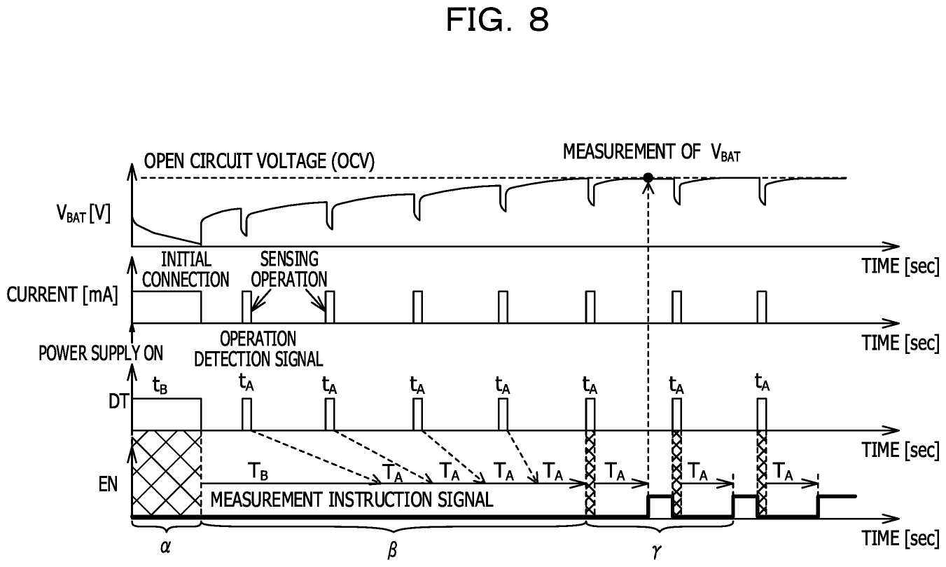

FIG. 8 is a diagram exemplifying a time chart indicating a time adjustment algorithm. First, since the initial connection is started after the turning on of the power supply, an operating current is detected by the initial connection operation. During a time period (time period α) for the initial connection, the battery voltage V_{BAT} significantly drops due to the current flowing due to the initial connection operation, and the open circuit voltage is not measured. Thus, the time adjuster 40 sets the measurement instruction signal EN for the battery voltage V_{BAT} to 0 during the time period α. When the initial connection operation is stopped and the operation detection signal DT is changed from 1 to 0, the time adjuster 40 uses the operation time period t_{B} for the initial connection operation to acquire the restoration time period T_{B} from the time adjustment table. Since it is regarded that the battery voltage V_{BAT} is not restored to the open circuit voltage until the restoration time period T_{B} elapses, the time adjuster 40 sets the measurement instruction signal EN to 0. When the sensing operation is executed within a time period during which the measurement instruction signal EN is set to 0, the time adjuster 40 uses operation time periods t_{A} to reference restoration time periods T_{A} from the time adjustment table and sequentially accumulate the restoration time periods T_{A} to a current restoration time period (to obtain an accumulated time period β). After that, when the accumulated restoration time period expires and actual elapsed time reaches time when the battery voltage V_{BAT} is to be measured, the time adjuster 40 sets the measurement instruction signal EN to 1. Thus, when the battery voltage V_{BAT} is actually restored to the open circuit voltage, the battery voltage V_{BAT} may be measured (during a time period γ). Since the open circuit voltage is reliably measured, the battery voltage to be used to estimate remaining battery power is measured only once. Thus, the accuracy of estimating remaining battery power with low power may be improved.

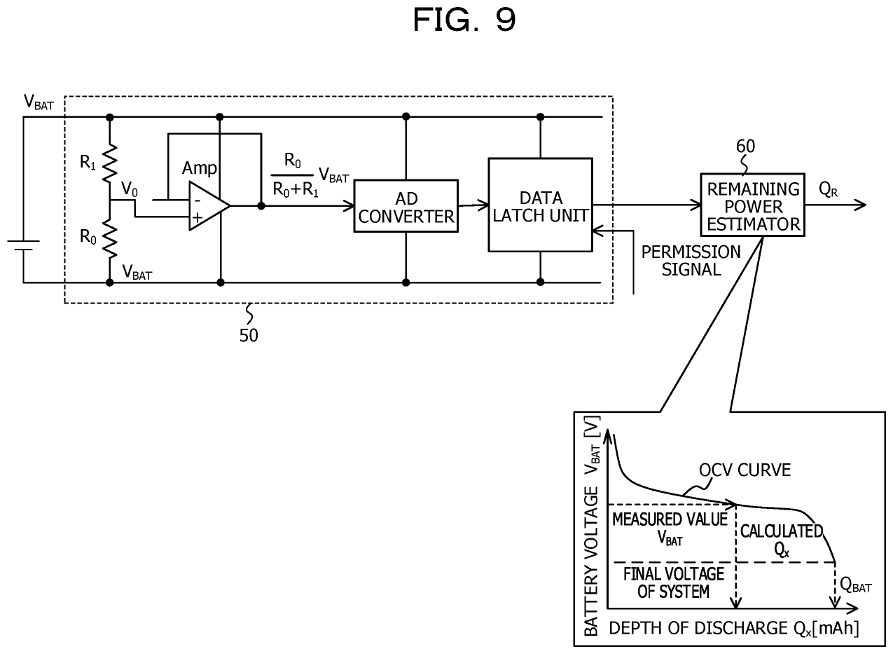

FIG. 9 is a diagram exemplifying the voltage measurer 50 and the remaining power estimator 60 in detail. As exemplified in FIG. 9, the voltage measurer 50 executes resistance division to reduce the level of the battery voltage V_{BAT}, causes an amplifier to amplify the battery voltage V_{BAT}, and causes an analog-to-digital (AD) converter to convert the battery voltage V_{BAT} so that the battery voltage V_{BAT} is measured. The voltage measurer 50 restores the level of the battery voltage V_{BAT} based on a resistance division ratio upon the estimation of remaining power of the battery 20. The voltage measurer 50 holds, in a data latch unit, the battery voltage V_{BAT} after the AD conversion. The remaining power estimator 60 references an open circuit voltage curve of the battery 20, acquires a depth Q_{X} of discharge from the battery voltage V_{BAT} obtained by the AD conversion and held in the data latch unit, and estimates remaining battery power Q_{R} from the depth Q_{X} of discharge. The data latch unit does not acquire the battery voltage V_{BAT} after the AD conversion until a permission signal is input to the data latch unit from the time adjuster 40. Alternatively, the permission signal may be input to the remaining power estimator 60, and the remaining power estimator 60 may not estimate remaining battery power until the measurement instruction signal EN=1 is input to the remaining power estimator 60. It is, however, preferable that the measurement instruction signal EN=1 be input to a portion in which a consumed current is significantly small in a time zone in which the measurement instruction signal EN=1 is not input to the remaining power estimator 60.

For example, in a certain sensor node, an average current consumed by a sensor unit is approximately 100 μA, a current of approximately 40 μA is consumed for continuous voltage measurement, and thus a total consumed current is approximately 140 μA. On the other hand, in the first embodiment, since the accuracy of measuring remaining battery power is maintained and a current to be consumed for the voltage measurement is suppressed to 5 μA or less, 140 μA may be reduced to 105 μA, and energy is reduced by approximately 33%. If power to be consumed by the sensor unit is saved more, and an average current to be consumed by the sensor unit is reduced by approximately half to 50 μA or the like, the rate of reducing energy increases to approximately 64% in the first embodiment.

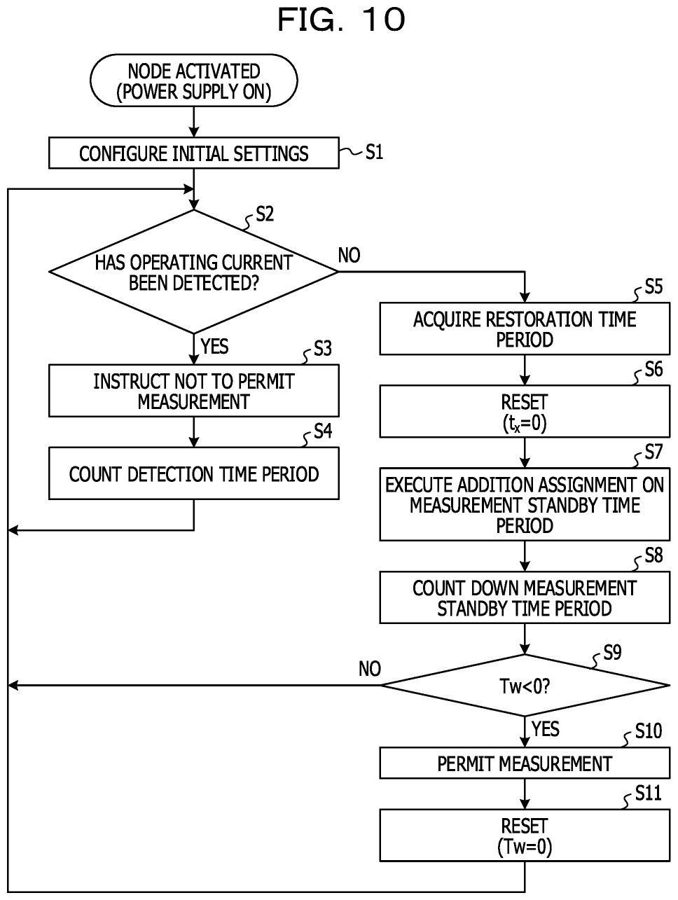

FIG. 10 is a diagram exemplifying a time chart indicating a time adjustment algorithm. As exemplified in FIG. 10, the time adjuster 40 configures initial settings (in step S1). For example, the time adjuster 40 sets t_{X}, T_{W}, and EN to 0. t_{X} indicates an operation time period register. T_{W} indicates a measurement standby time period register. Next, the time adjuster 40 determines whether an operating current is being detected by the operation detector 30 (in step S2). For example, the time adjuster 40 determines whether the operation detection signal DT indicates 1.

When the answer to step S2 is “Yes”, the time adjuster 40 sets the measurement instruction signal EN to 0 in order to instruct the voltage measurer 50 not to permit the measurement (in step S3). Next, the time adjuster 40 counts a detection time period (in step S4). For example, the time adjuster 40 sets an equation of t_{X}+t_{S}=t_{X}. t_{S} indicates a time step. After that, a process illustrated in FIG. 10 is executed again from step S2.

When the answer to step S2 is “No”, the time adjuster 40 references the time adjustment table and acquires a restoration time period T_{X} corresponding to the operation time period register t_{X} (in step S5). Then, the time adjuster 40 resets the operation time period register t_{X} to 0 (in step S6). Then, the time adjuster 40 executes addition assignment on the measurement standby time period register T_{W} (in step S7). For example, the time adjuster 40 sets an equation of T_{W}+T_{X}=T_{W}.

Then, the time adjuster 40 counts down the measurement standby time period register T_{W} (in step S8). For example, the time adjuster 40 sets an equation of T_{W}−t_{S}=T_{W}. After that, the time adjuster 40 determines whether the measurement standby time period register T_{W} is negative (in step S9). When the answer to step S9 is “No”, the process is executed again from step S2. When the answer to step S9 is “Yes”, the time adjuster 40 sets the measurement instruction signal EN to 1 in order to instruct the voltage measurer 50 to permit the measurement (in step S10). Then, the time adjuster 40 resets the measurement standby time period T_{W} to 0 (in step S11). After that, a process illustrated in FIG. 10 is executed again from step S2.

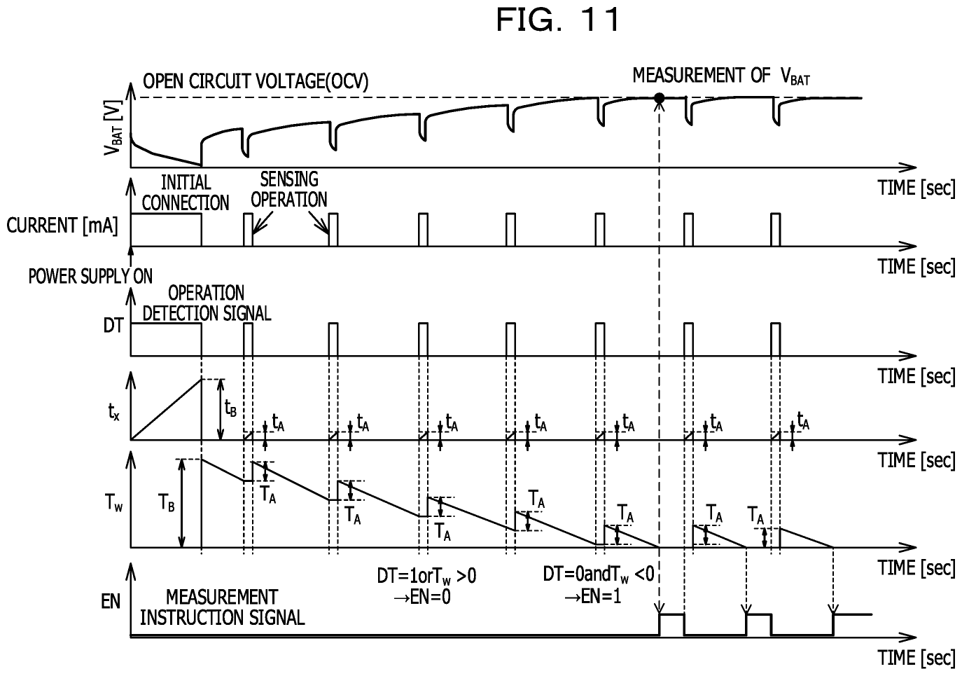

FIG. 11 is a diagram exemplifying a time chart when the process to be executed in accordance with the time adjustment algorithm described with reference to FIG. 10 is applied to the time chart illustrated in FIG. 8. During operation time periods (DT=1) of the sensor 12, the measurement is not permitted (EN=0). Every time the operation of the sensor 12 is detected, the time adjustment table is referenced from an operation time period (t_{X}) for the operation and a restoration time period (T_{X}) is acquired. The restoration time period T_{X} is accumulated to the measurement standby time period T_{W}. Even when the measurement standby time period T_{W}>0, the measurement is not permitted (EN=0). In addition, actual elapsed time is subtracted from the measurement standby time period T_{W}. In the case where the operation of the sensor 12 is not detected (DT=0) when the measurement standby time period T_{W} is lower than 0, a measurement permission signal is output (EN=1).

### Second Embodiment

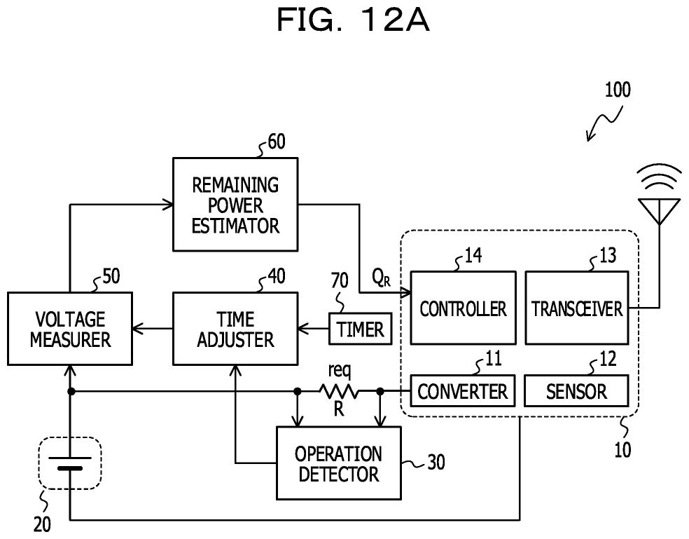

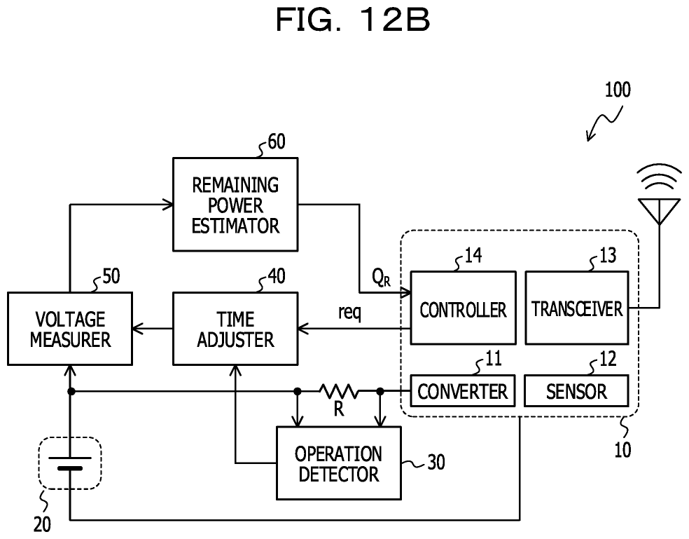

FIGS. 12A and 12B are diagrams exemplifying cases in which remaining battery power is estimated when a request signal is input. FIG. 12A exemplifies the case where a timer 70 included in the sensor node 100 periodically requests the estimation of remaining battery power. FIG. 12B exemplifies the case where the controller 14 requests the estimation of remaining battery power. In each of the cases, a request signal req is output and the time adjuster 40 receives the request signal req.

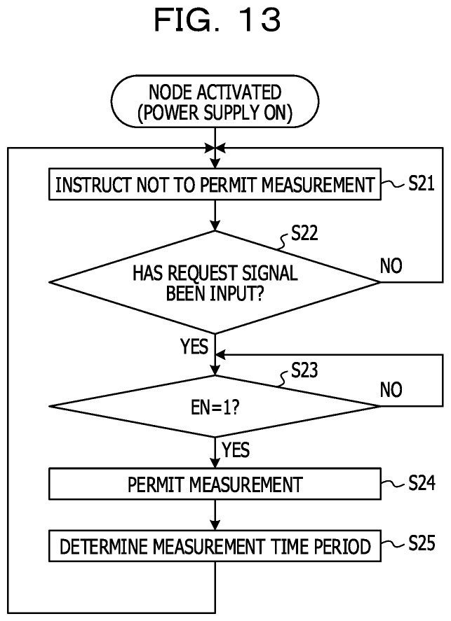

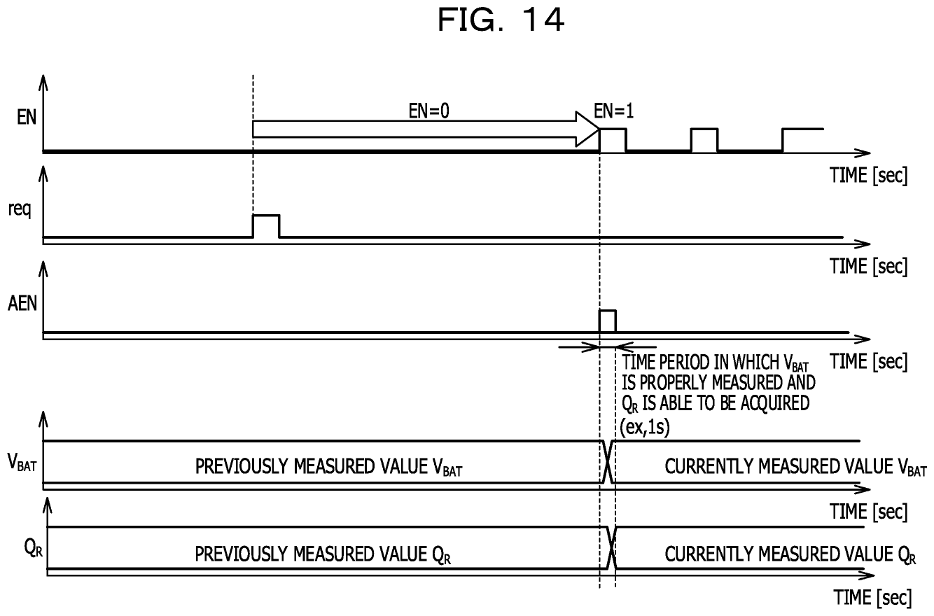

FIG. 13 is a diagram exemplifying a flowchart indicating a request process to be executed by the time adjuster 40 in each of the cases. FIG. 14 is a diagram exemplifying a time chart corresponding to the flowchart illustrated in FIG. 13. The time adjuster 40 sets a measurement instruction signal AEN to 0 (in step S21). Then, the time adjuster 40 determines whether a request signal req=1 has been input to the time adjuster 40 (in step S22). When the answer to step S22 is “No”, a process illustrated in FIG. 13 is executed again from step S21. Thus, the time adjuster 40 stands by until the request signal req=1 is input to the time adjuster 40.

When the answer to step S22 is “Yes”, the time adjuster 40 determines whether the measurement instruction signal EN=1 has been input to the time adjuster 40 (in step S23). When the answer to step S23 is “No”, the process is executed again from step S23. Thus, the time adjuster 40 stands by until the measurement instruction signal EN=1 is output. When the answer to step S23 is “Yes”, the time adjuster 40 outputs the measurement instruction signal AEN=1 to the voltage measurer 50 (in step S24). In this case, the time adjuster 40 determines a measurement time period (of, for example, 1 second) (in step S25). For example, a wasteful time period for the measurement of the battery voltage may be reduced to save power by issuing measurement permission only during a time period during which the battery voltage is properly measured and the remaining battery power (Q_{R}) is able to be estimated, and automatically canceling the measurement permission.

The flowchart illustrated in FIG. 10 is executed in parallel with the flowchart illustrated in FIG. 13. The voltage measurer 50 measures the battery voltage when the measurement instruction signal AEN=1 and the measurement instruction signal EN=1 are input to the voltage measurer 50.

According to a second embodiment, remaining battery power is not estimated until the estimation of the remaining battery power is requested. Thus, a wasteful time period for the measurement of the battery voltage may be reduced to save power to be consumed.

### Third Embodiment

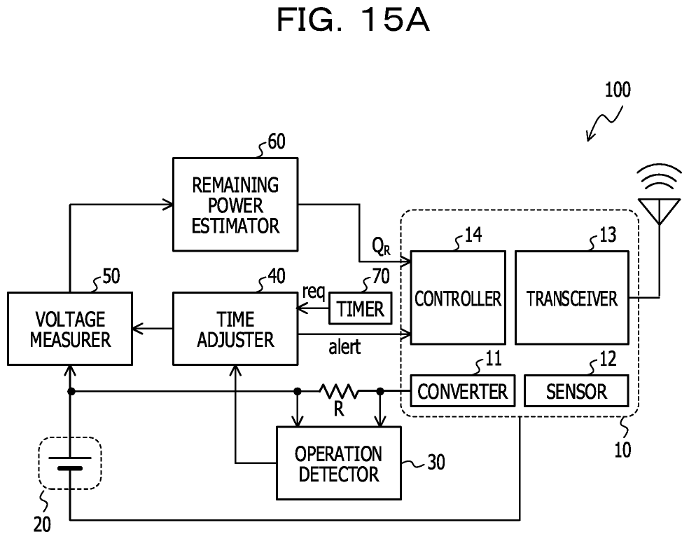

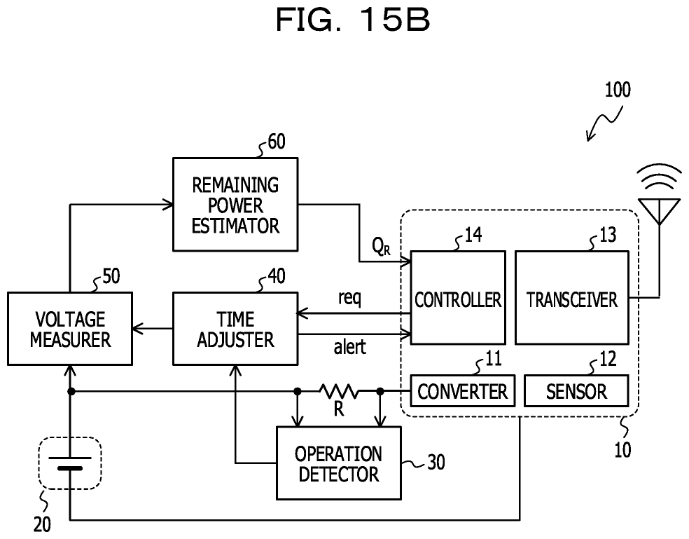

FIG. 15A is a diagram exemplifying the case where alarm transmission is executed when the timer 70 periodically requests the estimation of remaining battery power. FIG. 15B is a diagram exemplifying the case where alarm transmission is executed when the controller 14 periodically requests the estimation of remaining battery power. The examples illustrated in FIGS. 15A and 15B indicate the cases where a time period during which the battery voltage is measured decreases when the frequency at which the sensor 12 executes the sensing operation is high.

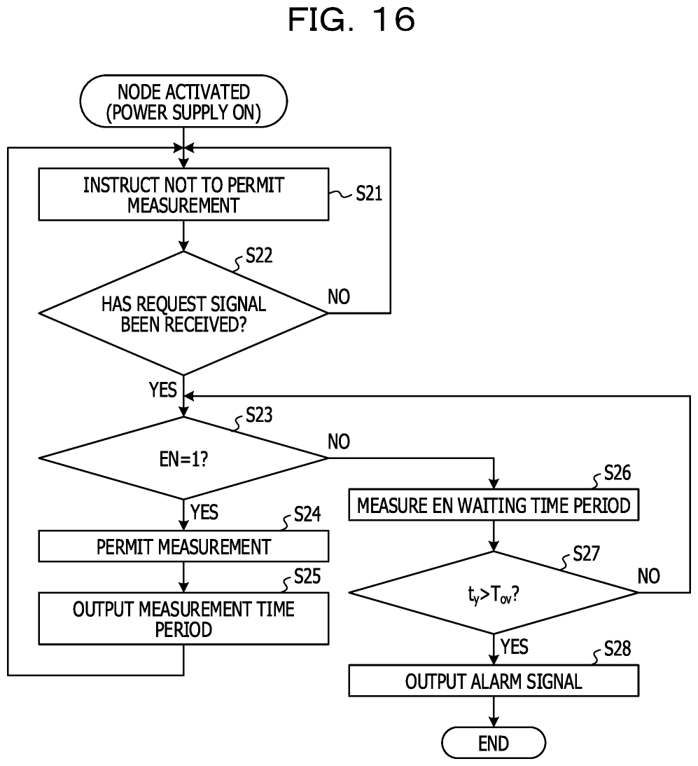

FIG. 16 is a diagram exemplifying a flowchart indicating a request process to be executed by the time adjuster 40 in the aforementioned case. As exemplified in FIG. 16, processes that are the same as or similar to steps S21 to S25 illustrated in FIG. 13 are executed. However, when the answer to step S23 is “No”, the time adjuster 40 measures an EN waiting time period (in step S26). For example, the time adjuster 40 sets an equation of t_{Y}+t_{S}=t_{Y}. In this case, t_{Y} indicates an EN waiting time period register. Then, the time adjuster 40 determines whether the EN waiting time period register t_{Y} exceeds a timeout setting time period T_{OV} (in step S27). When the answer to step S27 is “Yes”, the time adjuster 40 outputs an alarm signal (alert) indicating that the battery voltage is not measured (in step S28). When the answer to step S27 is “No”, a process illustrated in FIG. 16 is executed again from step S23.

According to a third embodiment, in the case where the measurement instruction signal EN=1 is not output even when the timeout setting time period T_{OV} elapses after the reception of the request signal req, an alarm signal (alert) is output. The transceiver 13 transmits the alarm signal. Thus, the managing server 202 may detect an abnormality of the sensor node 100.

### Fourth Embodiment

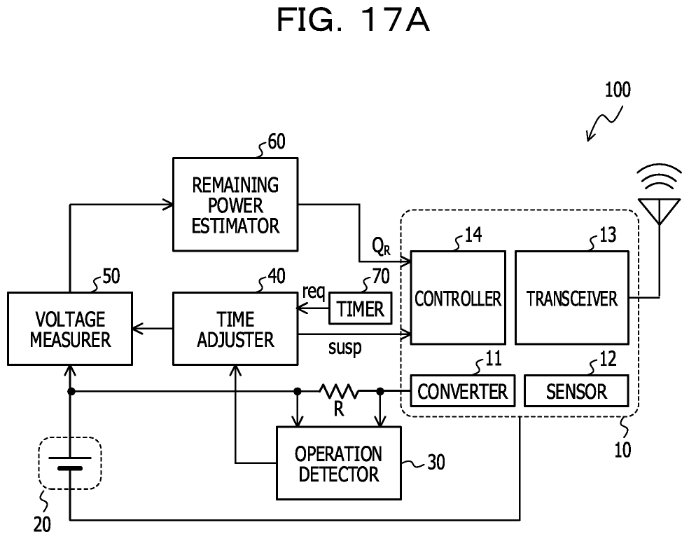

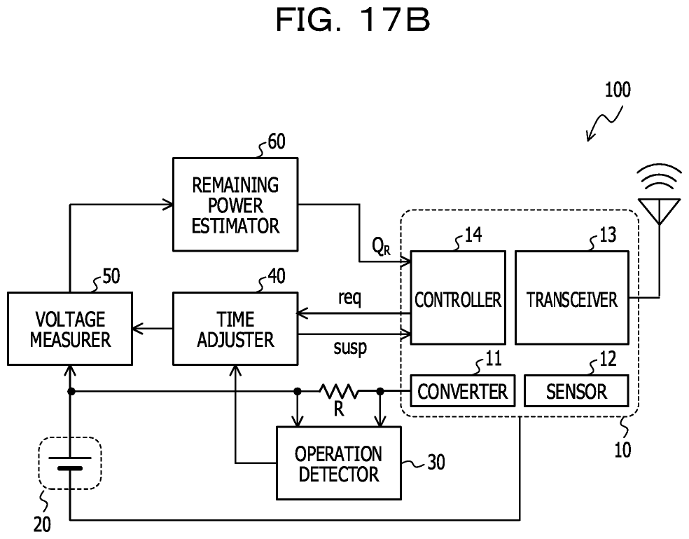

FIG. 17A is a diagram exemplifying the case where the sensing operation is suspended when the timer 70 periodically requests the estimation of remaining battery power. FIG. 17B is a diagram exemplifying the case where the sensing operation is suspended when the controller 14 periodically requests the estimation of remaining battery power. The examples illustrated in FIGS. 17A and 17B indicate the cases where a time period during which the battery voltage is measured decreases to 0 when the frequency at which the sensor 12 executes the sensing operation is high.

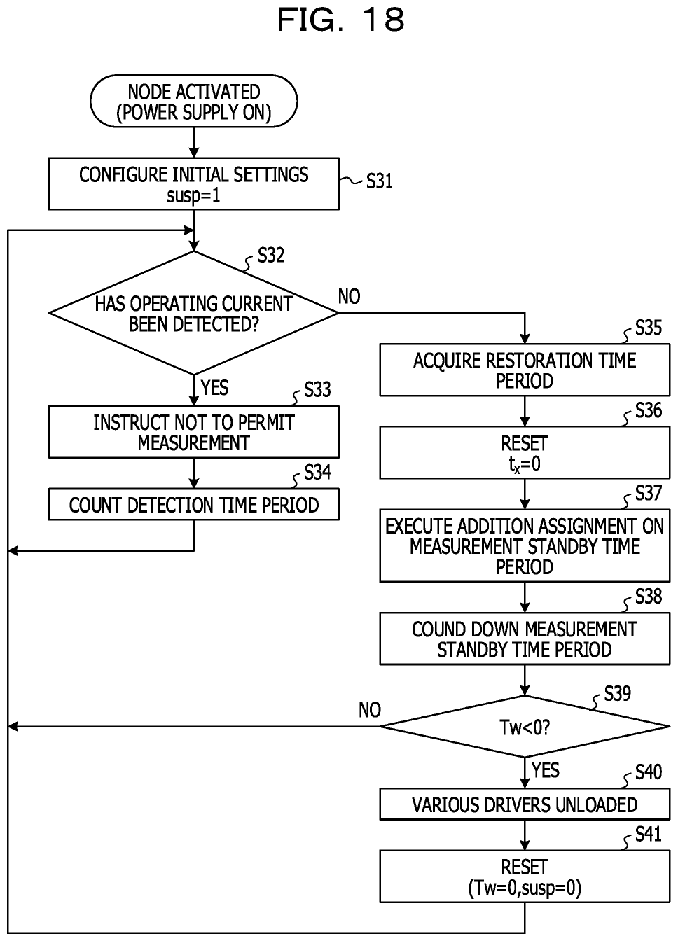

FIG. 18 is a diagram exemplifying a flowchart indicating a time adjustment algorithm in each of the cases. As exemplified in FIG. 18, the time adjuster 40 configures initial settings (in step S31). For example, the time adjuster 40 sets t_{X}, T_{W}, and EN to 0 and sets susp to 1. When susp is 1, the controller 14 inhibits the sensor 12 from executing the sensing operation. When susp is 0, the controller 14 cancels the inhibition of the sensing operation of the sensor 12.

After that, processes of steps S32 to S40 that are the same as or similar to steps S2 to S10 are executed. After the execution of step S40, the time adjuster 40 resets T_{W} to 0 and resets susp to 0 (in step S41). After that, a process illustrated in FIG. 18 is executed again from step S32. By executing this, the sensing operation of the sensor 12 may be suspended.

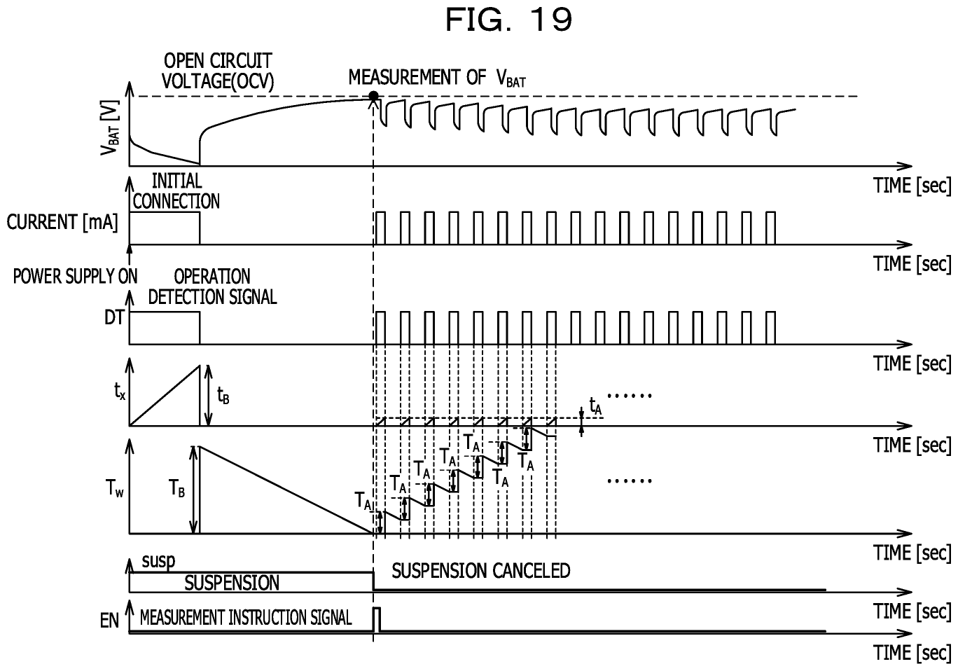

FIG. 19 is a diagram exemplifying a time chart when the frequency at which the sensing operation is executed is high and the flowchart illustrated in FIG. 18 is applied. Even when a suspension signal (susp=1) is output after the turning on of the power supply, and the initial connection operation is terminated, a processing operation of the sensor is not started. When the restoration time period T_{B} expires after the termination of the initial connection operation, the battery voltage is measured and initial remaining battery power is estimated. After that, the suspension is canceled (susp=0) and the process is normally executed. In an operational pattern illustrated in FIG. 19, if a suspension function does not exist, the value T_{W} is larger than 0 and the battery voltage is not measured. Remaining battery power immediately after the power supply is turned on may be properly estimated due to the existence of the suspension function.

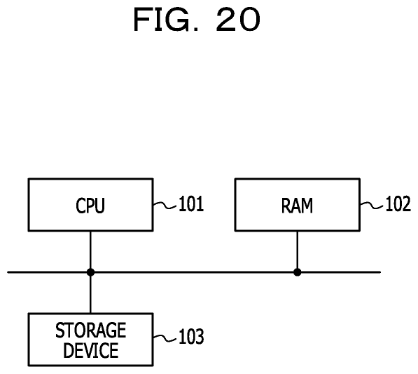

FIG. 20 is a block diagram describing a hardware configuration of the time adjuster 40. As exemplified in FIG. 20, the time adjuster 40 includes a central processing unit (CPU) 101, a random-access memory (RAM) 102, and a storage device 103. The devices 101 to 103 are connected to each other via a bus or the like. The CPU 101 includes one or more cores. The RAM 102 is a volatile memory that temporarily stores a program to be executed by the CPU 101, data to be processed by the CPU 101, and the like. The storage device 103 is a nonvolatile storage device. As the storage device 103, a read only memory (ROM), a solid state drive (SSD) such as a flash memory, a hard disk to be driven by a hard disk drive, or the like may be used, for example. The time adjuster 40 is enabled by causing the CPU 101 to execute a remaining battery power measuring device stored in the storage device 103. The time adjuster 40 may be constituted by a dedicated circuit or the like.

In the embodiments, the sensor node 100 includes the remaining power estimator 60. The embodiments are not limited to this. For example, the sensor node 100 may cause the transceiver 13 to transmit a measurement result of the voltage measurer 50, and the managing server 202 may execute the processes of the remaining power estimator 60. In the embodiments, the sensor 12 is used as a load that uses power supplied from the battery 20 to operate. Another load that uses power supplied from the battery 20 to operate may be used.

In the embodiments, the operation detector 30 functions as an example of a detector that detects an operation time period of an object that is to be measured and intermittently operates by power supplied from a battery. The time adjuster 40 functions as an example of a time adjuster that adjusts time when a battery voltage of the battery is measured, based on the operation time period detected by the detector. The voltage measurer 50 functions as an example of a measurer that measures the battery voltage at the time adjusted by the time adjuster. The remaining power estimator 60 functions as an example of an estimator that estimates remaining power of the battery based on the battery voltage measured by the measurer.

Although the embodiments are described above, the embodiments are not limited and may be variously modified and changed within the gist of the embodiments.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A remaining battery power measuring device comprising:
a memory; and
a processor coupled to the memory and configured to:
detect an operation time period of an object that is to be measured and intermittently operates by power supplied from a battery;
adjust time when a battery voltage of the battery is measured, based on the operation time period detected by the processor; and
measure the battery voltage at the time adjusted by the processor.

2. The remaining battery power measuring device according to claim 1, wherein
the processor holds, as a table, relationships between an operation time period of the battery and time when the battery voltage is measured, and the processor references the table and adjusts the time when the battery voltage is measured.

3. The remaining battery power measuring device according to claim 2, wherein
the table is acquired by measuring the battery voltage by the measurer after the object to be measured is operated.

4. The remaining battery power measuring device according to claim 1, wherein
the processor detects the operation time period based on a current flowing from the battery to the object to be measured.

5. The remaining battery power measuring device according to claim 1, wherein
the processor measures the battery voltage during a time period other than the operation time period.

6. The remaining battery power measuring device according to claim 1, wherein
when the processor detects a next operation time period of the object to be measured after the operation time period and before the time when the battery voltage is measured, the processor delays, based on the next operation time period, the time when the battery voltage is measured.

7. The remaining battery power measuring device according to claim 1, wherein
the processor measures the battery voltage after receiving a request signal.

8. The remaining battery power measuring device according to claim 7, wherein
in the case where the measurement of the battery voltage is not executed even when predetermined time elapses after the reception of the request signal, the processor outputs an alarm signal.

9. The remaining battery power measuring device according to claim 1, wherein
the processor suspends, during a predetermined time period, an operation of the object to be measured.

10. The remaining battery power measuring device according to claim 9, wherein
the processor suspends the operation of the object to be measured until the battery voltage is measured one or more times upon an initial operation of the object to be measured.

11. The remaining battery power measuring device according to claim 1, wherein
the processor estimates remaining power of the battery based on the measured battery voltage.

12. The remaining battery power measuring device according to claim 11, wherein
the processor estimates the remaining power of the battery using a table indicating relationships between an open circuit voltage of the battery and remaining power of the battery.

13. The remaining battery power measuring device according to claim 1, wherein
the object to be measured is a sensor that outputs a sensing result obtained by a sensing operation.

14. A method of measuring remaining battery power, comprising:
detecting an operation time period of an object that is to be measured and intermittently operates by power supplied from a battery;
adjusting time when a battery voltage of the battery is measured, based on the detected operation time period; and
measuring the battery voltage at the adjusted time.

15. The method according to claim 14, wherein
the adjustment of the time when the battery voltage is measured is executed by referencing a table indicating relationships between an operation time period of the battery and time when the battery voltage is measured.

16. A non-transitory computer-readable storage medium storing a program that causes a processor included in a computer to execute a process, the process comprising:
detecting an operation time period of an object that is to be measured and intermittently operates by power supplied from a battery;
adjusting time when a battery voltage of the battery is measured, based on the detected operation time period; and
measuring the battery voltage at the adjusted time.
